(19) United States
(12) Patent Application Publication
(10) Pub. No.: US 2024/0339367 A1
(43) Pub. Date: Oct. 10, 2024

(54) Erasable Nanocellulose Electronics

(71) Applicant: The Government of the United States of America, as represented by the Secretary of the Navy, Arlington, VA (US)

(72) Inventors: Jonathan D. Yuen, Washington, DC (US); Mona Ebrish, Nashville, TN (US)

(73) Assignee: The Government of the United States of America, as represented by the Secretary of the Navy, Arlington, VA (US)

(21) Appl. No.: 18/617,553

(22) Filed: Mar. 26, 2024

Related U.S. Application Data
(60) Provisional application No. 63/494,323, filed on Apr. 5, 2023.

(51) Int. Cl. H01L 23/14; H01L 23/58; H01L 33/62

(52) U.S. Cl. CPC H01L 23/145; H01L 23/58; H01L 33/62

(57) ABSTRACT

A method of making an erasable nanocellulose electronic structure comprising the steps of providing a nanocellulose sheet, adhering metal contacts onto the nanocellulose sheet, applying solder to the metal contacts, and attaching surface mount devices to the contacts. An erasable nanocellulose electronic structure comprising a nanocellulose sheet, a metal contact on the nanocellulose sheet, a layer of solder on the metal contact, and a surface mount device to the contact.

### REFERENCE TO RELATED APPLICATION

This application is a non-provisional of, and claims priority to and the benefits of, U.S. Provisional Patent Application No. 63/494,323 filed on Apr. 5, 2023, the entirety of which is herein incorporated by reference.

### BACKGROUND

This disclosure concerns a new erasable nanocellulose electronic device and a new mechanism to imbue electronics built on microbial nanocellulose with transient or self-destructing properties.

This relies on the loss of adhesion under mechanical action that bacterial nanocellulose experiences when saturated with water.

The prior art, in contrast, relies on the intrinsic fragmentation of the materials on which they were built from, or the destructive action from an agent external to the electronic devices.

Here, the transience of these nanocellulose electronics rely on the mechanical decoupling on the components due to a loss of mutual adhesion and mutual cohesion, and the subsequent disintegration from mechanical instabilities upon decoupling. Here, the electronic components separate and fragment from each other through adhesion loss and mechanical action.

Transient electronics are a specialized form of electronics that are specifically designed to dissociate in a systematically programmed manner—an induced transience.

The applications of transient electronics contrast with standard modern electronics which are designed to be mechanically, chemically, and operationally stable over a long period of time.

Such applications of our new erasable nanocellulose electronics include temporary or biosorbable medical devices for implants or drug-delivery, sustainable eco-friendly electronics, wearable electronics, and stealth applications for military or government missions.

Currently, all transient electronics fall into three categories or a combination thereof: firstly, through the use of electronic materials that are engineered to degrade in the presence of stimuli; secondly, by the triggered release of a highly reactive chemical that induces disintegration; and thirdly, by biological action.

Notable examples of the first prior art approach, engineered electronic materials, include water soluble electronics made with a combination of ultra-thin silicon, magnesium oxide and magnesium on water soluble substrates, such as polyvinyl-alcohol; and electronics made on environmentally sensitive materials such as ignitable polycaprolactone or nitrocellulose substrates, strained glass substrates which shatter when heated (VAPR by PARC-Xerox), cyclododecane substrates which sublime in ambient conditions, and moisture-sensitive polyanhydrides which hydrolyze in ambient water vapor.

The disadvantages of these prior art specialized materials design is the limitation of usable materials and the cost to create such materials, both in terms of synthesis and design of processing methods.

The second prior art approach, the triggered release of a highly reactive chemical, offers an advantage over the first approach as it does not require engineering of new and specialized materials. Two methods are typically employed to trigger the release of the chemical, which is typically a corrosive acid. One is via phototriggered release of the acid, either through an optically-sensitive metastable polymer, or through the photoinduced generation of a photoacid. The other is to seal the acid in a wax compartment and release the acid thermally.

The disadvantages of this prior art approach are the need for a corrosive or dangerous chemical, which creates logistics and manufacturing issues.

The final prior art approach is selecting materials which are biodegradable, i.e. they can be degraded via enzymatic action by bacteria and fungi. A large variety of materials can be biodegraded. These include polysaccharides such as starches and cellulose, DNA, polypeptides such as silk, gelatin and pectin, plant polymers such as shellac, semiconducting natural products such indigo, melanin and ß-carotene.

The disadvantages of this prior art approach, however, are the timescales for degradation are extremely long, requiring days to months for complete degradation to occur.

For the prior art, the first approach relies on the intrinsic behavior of the material to disaggregate, while the last two approaches rely on the action of external agents for disintegration.

To solve these prior art issues this disclosure demonstrates a new mechanism to imbue electronics built on microbial nanocellulose with transient or self-destructing properties.

This relies on the loss of adhesion under mechanical action that bacterial nanocellulose experiences when saturated with water.

The prior art, in contrast, relies on the intrinsic fragmentation of the materials on which they were built from, or the destructive action from an agent external to the electronic devices.

Here, we demonstrate a novel erasable nanocellulose electronic device.

As described herein, the transience of these nanocellulose electronics rely on the mechanical decoupling on the components due to a loss of mutual adhesion and mutual cohesion, and the subsequent disintegration from mechanical instabilities upon decoupling.

Here, the electronic components separate and fragment from each other through adhesion loss and mechanical action, not with external agent, as in the prior art.

### SUMMARY OF DISCLOSURE

### Description

This disclosure concerns a new erasable nanocellulose electronic device and a new mechanism to imbue electronics built on microbial nanocellulose with transient or self-destructing properties.

This relies on the loss of adhesion under mechanical action that bacterial nanocellulose experiences when saturated with water.

Here, we demonstrate a novel erasable nanocellulose electronic device.

As described herein, the transience of these nanocellulose electronics rely on the mechanical decoupling on the components due to a loss of mutual adhesion and mutual cohesion, and the subsequent disintegration from mechanical instabilities upon decoupling.

Here, the electronic components separate and fragment from each other through adhesion loss and/or mechanical action, not with external agent, as in the prior art.

Our invention relies on the unique adhesive properties of bacterial nanocellulose in which nanocellulose adheres very strongly to certain materials when dry, but loses its adhesive properties when the porous nanocellulose is soaked with water.

Electronics fabricated on the surface of nanocellulose adhere onto nanocellulose when dry but decouple from the substrate when wet, allowing them to be removed and disintegrated through mechanical action, if desired or required.

### DESCRIPTION OF THE DRAWINGS

The following description and drawings set forth certain illustrative implementations of the disclosure in detail, which are indicative of several exemplary ways in which the various principles of the disclosure may be carried out. The illustrated examples, however, are not exhaustive of the many possible embodiments of the disclosure. Other objects, advantages and novel features of the disclosure will be set forth in the following detailed description when considered in conjunction with the drawings.

FIG. 1 illustrates a nanocellulose sheet adhered onto a glass wafer (left), and the sheet peeled off the wafer when wet (right).

FIG. 2 illustrates gold electrodes evaporated onto a nanocellulose sheet (left) and their delamination from the sheet after immersion in a dish of water.

FIG. 3 illustrates the process flowchart in which the transient electronics are fabricated.

FIG. 4 illustrates a transient electronic device consisting of a flashing LED connected to a surface mount lithium ion battery.

FIG. 5 illustrates both devices in FIG. 4 in operation with a drop of water added to a section of the electrode, with the section about to be erased with a cotton swab. After rubbing briefly with the swab, the electrode is removed from the substrate, thereby disabling the LED.

### DETAILED DESCRIPTION OF THE INVENTION

This disclosure concerns a new erasable nanocellulose electronic device and a new mechanism to imbue electronics built on microbial nanocellulose with transient or self-destructing properties.

This relies on the loss of adhesion under mechanical action that bacterial nanocellulose experiences when saturated with water.

Here, we demonstrate a novel erasable nanocellulose electronic device.

As described herein, the transience of these nanocellulose electronics rely on the mechanical decoupling on the components due to a loss of mutual adhesion and mutual cohesion, and the subsequent disintegration from mechanical instabilities upon decoupling.

Here, the electronic components separate and fragment from each other through adhesion loss and/or mechanical action, not with external agent, as in the prior art.

Our invention relies on the unique adhesive properties of bacterial nanocellulose in which nanocellulose adheres very strongly to certain materials when dry, but loses its adhesive properties when the porous nanocellulose is soaked with water.

Electronics fabricated on the surface of nanocellulose adhere onto nanocellulose when dry but decouple from the substrate when wet, allowing them to be removed and disintegrated through mechanical action, if desired or required.

### Example 1

A method of making an erasable nanocellulose electronic structure, comprising the steps of providing a glass wafer, applying a nanocellulose sheet to the glass wafer, adhering metal contacts onto the nanocellulose sheet, applying solder to the metal contacts, and attaching surface mount devices to the contacts.

### Example 2

The method of making the erasable nanocellulose electronic structure, wherein the nanocellulose is microbial.

### Example 3

The method of making the erasable nanocellulose electronic structure, wherein the step of applying metal contacts comprises shadow mask evaporation and wherein the metal contacts comprise gold.

### Example 4

The method of making the erasable nanocellulose electronic structure, further including the steps of heating the glass wafer and melting the solder.

### Example 5

The method of making the erasable nanocellulose electronic structure of claim 5, further including the steps of stimulating via hydrostimulation the loss of adhesion between the metal contacts and the nanocellulose sheet and destroying the erasable nanocellulose electronic structure.

Additionally, mechanical action was applied in some embodiments.

Described herein is a new erasable nanocellulose electronic device.

This transient destructible device relies on the hydrostimulated loss of adhesion of electronic components of fabrication on nanocellulose.

The destruction of the device is loss of adhesion alone, or can be coupled with mechanical action, such as rubbing.

### Example 6

Our invention concerns the unique adhesive properties of bacterial nanocellulose in which nanocellulose adheres very strongly to certain materials when dry, but loses its adhesive properties when the porous nanocellulose is soaked with water.

The hydroxyl bonds along the sides of the cellulose polymer chain contribute to hydrogen bonding, which becomes disrupted from electronic shielding when surrounded by water molecules.

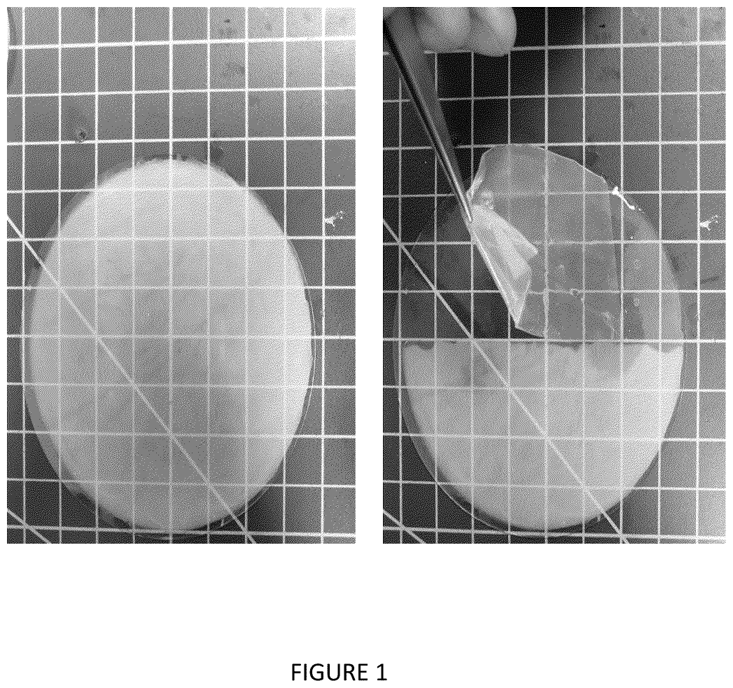

FIG. 1 illustrates an example of this phenomenon, in which a nanocellulose sheet is adhered to a glass wafer so strongly that it is impossible to peel it off.

However, once the sheet is lightly moisturized with some water, it can be peeled off very easily.

### Example 7

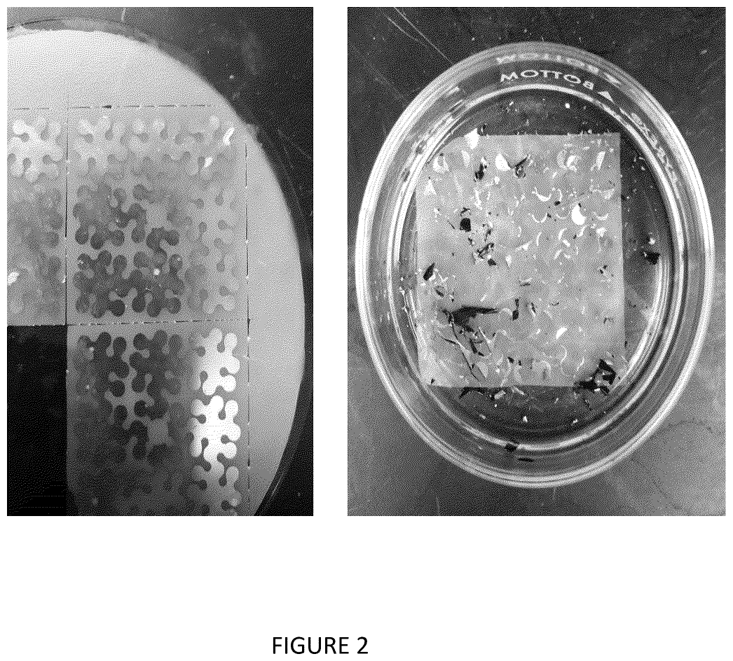

This phenomenon also occurs with thin metal films evaporated onto nanocellulose, as shown in FIG. 2, where gold films are evaporated onto a nanocellulose sheet.

When dry, the gold films cannot be removed with rubbing.

However, when the sheets are immersed in a water bath for less than an hour, the gold film automatically delaminates from the sheet and forms a separate free-floating film in the water under strong agitation.

The gold films without the mechanical backing of the nanocellulose are thin and mechanically fragile, and we can observe that part of the gold film floating in the water has already disintegrated.

### Example 8

An erasable nanocellulose electronic structure, comprising a glass wafer, a nanocellulose sheet on the glass wafer, a metal contact on the nanocellulose sheet, a layer of solder on the metal contact, and a surface mount device to the contact.

The erasable nanocellulose electronic structure can concern wherein the nanocellulose is microbial.

The erasable nanocellulose electronic structure can concern wherein the metal contacts comprise gold.

A transient electronic device in which the gold films are patterned as electrodes and connected to electronic components was based on the phenomenon described previously.

In the presence of water and mechanical action, the electrodes and electronic components will decouple from the sheet, become mechanically unstable and disintegrate, resulting in loss of operation.

This is in contrast to the prior art approaches of transient electronics as described above which either rely on the intrinsic behavior of the material to disaggregate, or rely on the action of destructive external agents for disintegration.

Our approach towards disaggregation instead relies on mechanical instabilities resulting from the device components decoupling due to loss of adhesion.

### Example 9

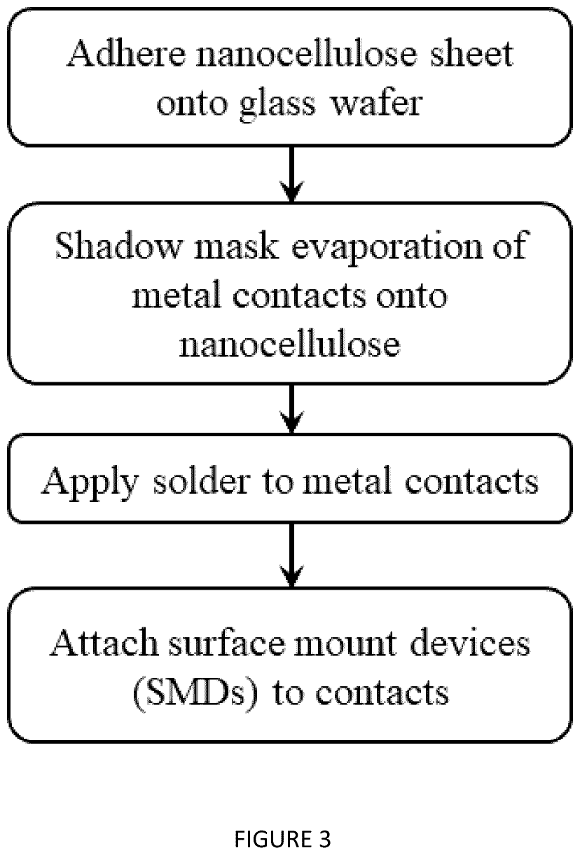

Fabrication of the device follows a process flow listed in FIG. 3 and is simple to implement with current available manufacturing processes.

Firstly, a nanocellulose sheet is adhered onto a glass wafer to anchor and stabilize it structurally.

Secondly, gold electrodes are evaporated onto the nanocellulose sheet surface via a shadow mask stencil.

Then solder is applied to specific locations on the electrodes where surface mount electronic components (SMDs) will be linked to the electrodes.

Finally, the substrate is placed on a hot plate to melt the solder, and the SMDs mounted at the solder joints to connect them to the circuit.

The substrate is then left to cool and the transient device is completed.

### Example 10

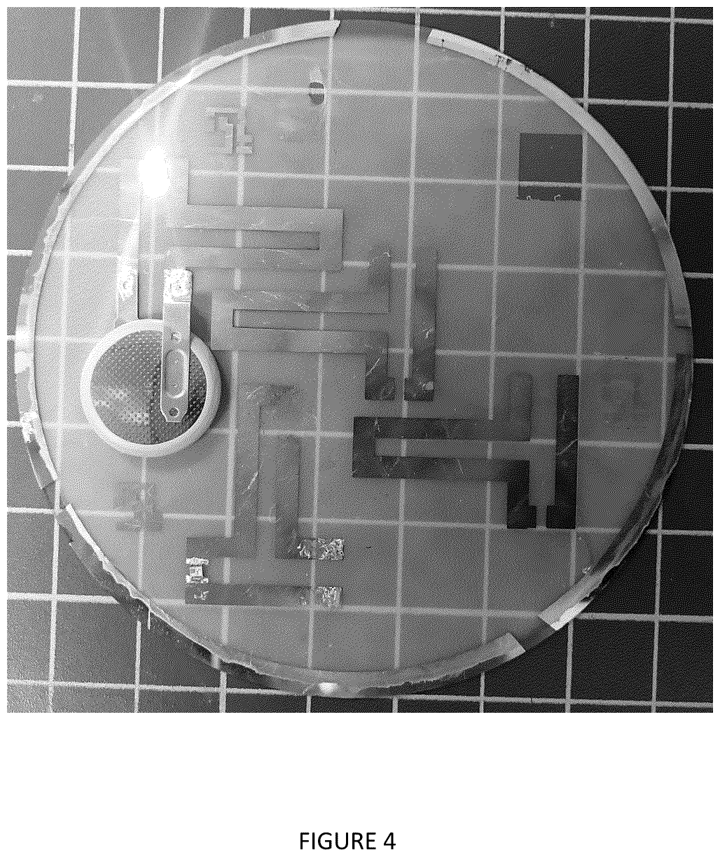

FIG. 4 shows an example of a transient device, which is a simple circuit consisting of a multicolored flashing LED connected to a lithium ion battery SMD.

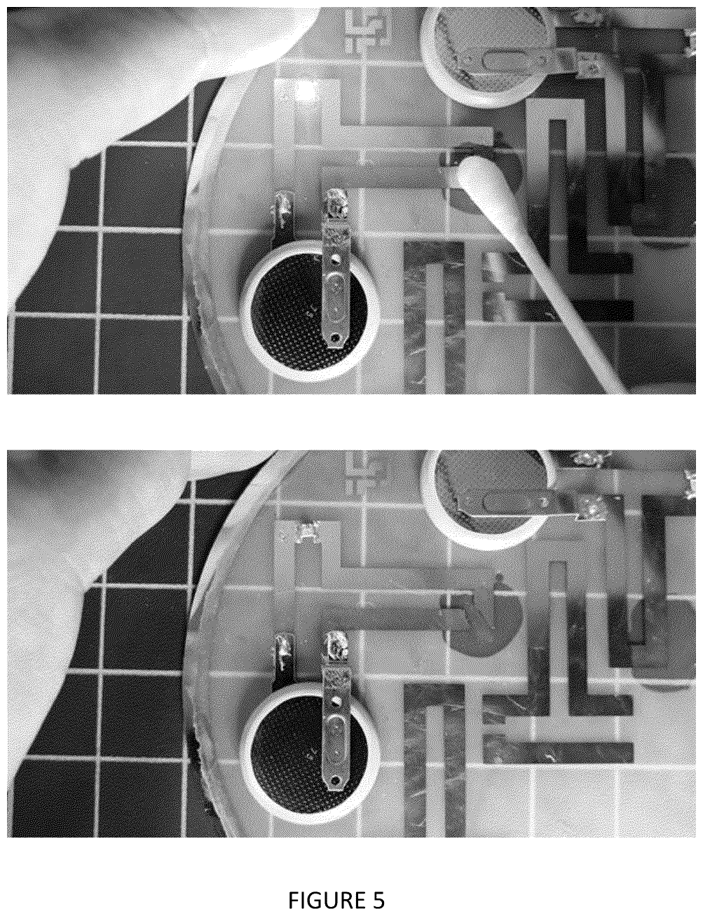

The transient nature of the nanocellulose-based LED circuit can be easily observed in FIG. 5.

The top image of FIG. 5 shows the device in operation at the start when a drop of water was placed on a small section of a gold electrode of the device, followed by rubbing the immersed section of electrode with a cotton swab.

We observe the cessation of operation of the nanocellulose device as the section of electrode where the water droplet was had been completely delaminated by the mechanical removal of the electrode with the electrode.

The presence of water loosens the electrode from the nanocellulose substrate, allowing it to be removed simply by mechanical rubbing.

### Advantages

Our approach described herein offers certain advantages over the prior art paradigms.

Nanocellulose is advantageous as it is low cost and ubiquitous. It is grown in industrial quantities as a food product known as nata de coco.

Furthermore, nanocellulose is inert and biocompatible, and therefore can be used for multiple applications, including medicine.

Additionally, nanocellulose can be used as the substrate. In other words, nanocellulose can be used without the use of a substrate or additional substrate, for example, without a glass wafer or in the absence of another substrate.

Moreover, the concept of switching on and off adhesion to induce transience is observed in nanocellulose.

Our approach has many advantages over the use of reactive or dangerous materials, such as corrosive acids, shattering glass, and flammable materials, as such properties will limit the utility and the ability to handle devices that contain such risky materials.

Finally, our mechanism of transience occurs quickly, with the operation of our devices disabled and disintegrated in less than an hour, comparable to devices made using the first two prior art approaches, and substantially faster than the prior art biodegradation approach.

Any electronic materials can be utilized including but not limited to metals such as aluminum, silver, copper, metallic compounds such zinc oxide, indium tin oxide, other oxides, borides, chalcogenides, pnicitides, perovskites and nitrides, doped or charged semiconductors, and metalloids such as boron, germanium, antimony, bismuth and graphene.

Any porous materials can be utilized in which adhesion can be programmed to switch on and off including intrinsic polymers, modified polymers, mesoporous and microporous organic and inorganic systems, MOFs, zeolites, biomaterials, hydrogels.

Alternative stimuli to switch adhesion on and off can be utilized including radiation, heat, gaseous or liquid chemicals.

Alternative form factors can be utilized, such as blocks, oblongs, elipsoids, ribbons, fibrils, tubes, rods, and other 2D and 3D structures, both filled and hollow.

Alternative methods can be utilized for device formation, such as PCB fabrication, inkjet printing, screen-printing, lithography, gravure, roll-to-roll, spray-printing, batik, laser, flexography, thermal-printing, stamping, intaglio, lamination, and adhesion.

The above examples are merely illustrative of several possible embodiments of various aspects of the present disclosure, wherein equivalent alterations and/or modifications will occur to others skilled in the art upon reading and understanding this specification and the annexed drawings. In addition, although a particular feature of the disclosure may have been illustrated and/or described with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising”.

What we claim is:

1. A method of making an erasable nanocellulose electronic structure, comprising the steps of:
providing a nanocellulose sheet;
adhering metal contacts onto the nanocellulose sheet;
applying solder to the metal contacts; and
attaching surface mount devices to the contacts.

2. The method of making an erasable nanocellulose electronic structure of claim 1,
wherein the nanocellulose is microbial.

3. The method of making an erasable nanocellulose electronic structure of claim 2,
wherein the step of applying metal contacts comprises shadow mask evaporation.

4. The method of making an erasable nanocellulose electronic structure of claim 3,
wherein the metal contacts comprise gold.

5. The method of making an erasable nanocellulose electronic structure of claim 4, further including the steps of:
providing a glass wafer;
applying the nanocellulose sheet to the glass wafer;
heating the glass wafer; and
melting the solder.

6. The method of making an erasable nanocellulose electronic structure of claim 5, further including the steps of:
stimulating via hydrostimulation the loss of adhesion between the metal contacts and the nanocellulose sheet; and
destroying the erasable nanocellulose electronic structure.

7. The method of making an erasable nanocellulose electronic structure of claim 5, further including the steps of:
stimulating via hydrostimulation the loss of adhesion between the metal contacts and the nanocellulose sheet;
applying mechanical action; and
destroying the erasable nanocellulose electronic structure.

8. An erasable nanocellulose electronic structure, comprising:
a nanocellulose sheet;
a metal contact on the nanocellulose sheet;
a layer of solder on the metal contact; and
a surface mount device to the contact.

9. The erasable nanocellulose electronic structure of claim 8,
wherein the nanocellulose is microbial.

10. The erasable nanocellulose electronic structure of claim 9,
wherein the metal contacts comprise gold.

11. An erasable nanocellulose electronic structure formed by the process comprising the steps of:
providing a nanocellulose sheet;
adhering metal contacts onto the nanocellulose sheet;
applying solder to the metal contacts; and
attaching surface mount devices to the contacts.

12. The erasable nanocellulose electronic structure of claim 11,
wherein the nanocellulose is microbial.

13. The erasable nanocellulose electronic structure of claim 12,
wherein the step of applying metal contacts comprises shadow mask evaporation.

14. The erasable nanocellulose electronic structure of claim 13, further including the steps of:
providing a glass wafer;
applying the nanocellulose sheet to the glass wafer;
heating the glass wafer; and
melting the solder.

15. The erasable nanocellulose electronic structure of claim 14, further comprising the steps of:
stimulating via hydrostimulation the loss of adhesion between the metal contacts and the nanocellulose sheet; and
destroying the erasable nanocellulose electronic structure.

16. The erasable nanocellulose electronic structure of claim 14, further comprising the steps of:
stimulating via hydrostimulation the loss of adhesion between the metal contacts and the nanocellulose sheet;
applying mechanical action; and
destroying the erasable nanocellulose electronic structure.

17. The erasable nanocellulose electronic structure of claim 14, further comprising the steps of:
shielding hydrogen bonds formed from hydroxyl sidegroups on the cellulose sheet which form with the metal contacts.

18. The erasable nanocellulose electronic structure of claim 17, further including the steps of:
breaking hydrogen bonds formed on the glass wafer by utilizing hydrostimulation.
